(19) United States
(12) Patent Application Publication
(10) Pub. No.: US 2012/0199924 A1
(43) Pub. Date: Aug. 9, 2012

(54) BSI IMAGE SENSOR PACKAGE WITH VARIABLE LIGHT TRANSMISSION FOR EVEN RECEPTION OF DIFFERENT WAVELENGTHS

(75) Inventors: Vage Oganesian, Palo Alto, CA (US); Belgacem Haba, Saratoga, CA (US); Ilyas Mohammed, Santa Clara, CA (US); Piyush Savalia, Santa Clara, CA (US); Craig Mitchell, San Jose, CA (US)

(73) Assignee: TESSERA RESEARCH LLC, San Jose, CA (US)

(21) Appl. No.: 13/020,328

(22) Filed: Feb. 3, 2011

(51) Int. Cl. H01L 31/0232; H01L 31/18

(52) U.S. Cl. 257/432; 438/72; 257/E31.127; 257/E31.001

(57) ABSTRACT

A microelectronic image sensor assembly for backside illumination and method of making same are provided. The assembly includes a microelectronic element having contacts exposed at a front face and light sensing elements arranged to receive light of different wavelengths through a semiconductor region adjacent a rear face. The semiconductor region has a first region of material overlying the first light sensing element and a second region of material overlying the second light sensing element such that the first and second wavelengths are able to pass through the first and second regions, respectively, and reach the first and second light sensing elements with substantially the same intensity.

### BACKGROUND OF THE INVENTION

The present invention relates to backside illuminated (“BSI”) image sensors, and in particular, the formation of same for even reception of different wavelengths of light.

Image sensors attempt to capture incident light into signals that accurately record intensity and color information with good spatial resolution. Front side illuminated (“FSI”) image sensors have photodetectors on silicon chips over which a circuitry layer including many levels of wiring is built up. In FSI image sensors, the light reaching the photodetectors must pass through the circuitry layer first. One limitation of FSI image sensors is that the circuitry layer can limit the exposed area, or aperture, of each pixel. As pixel sizes shrink in FSI image sensors due to increasing demands for higher numbers of pixels and smaller chip sizes, the ratio of pixel area to the overall sensor area decreases. This can reduce the quantum efficiency of the sensor.

This concern is addressed somewhat by backside illumination image sensors in which light enters the sensor from the back of the chip, thus avoiding the circuitry layer. However, in BSI image sensors, the light must still pass through the silicon that lies between the back of the chip and the photodetectors. This can also pose particular challenges, as will be further described herein. Further improvements can be made to BSI image sensors which may help to overcome deficiencies of current devices.

Size is a significant consideration in any physical arrangement of chips. The demand for more compact physical arrangements of chips has increased even more with the rapid progress of portable electronic devices. Merely by way of example, devices commonly referred to as “smart phones” integrate the functions of a cellular telephone with powerful data processors, memory and ancillary devices such as global positioning system receivers, electronic cameras, and local area network connections along with high-resolution displays and associated image processing chips. Such devices can provide capabilities such as full internet connectivity, entertainment including full-resolution video, navigation, electronic banking and more, all in a pocket-size device. Complex portable devices require packing numerous chips into a small space. Moreover, some of the chips have many input and output connections, commonly referred to as “I/O's.” These I/O's must be interconnected with the I/O's of other chips. The interconnections should be short and should have low impedance to minimize signal propagation delays. The components which form the interconnections should not greatly increase the size of the assembly. Similar needs arise in other applications as, for example, in data servers such as those used in internet search engines. For example, structures which provide numerous short, low-impedance interconnects between complex chips can increase the bandwidth of the search engine and reduce its power consumption.

### BRIEF SUMMARY OF TEE INVENTION

Embodiments of the invention herein can include a microelectronic element having materials of varying reflectivity or a material having different areas with different properties of varying reflectivity overlying a plurality of light sensing elements therein. By varying the materials, the absorption of light by the silicon at each photodiode can be made more uniform for light of different wavelengths, such that the light sensing elements, e.g., photodiodes, receive light of different wavelengths at substantially the same intensity.

A first aspect of the present invention is a microelectronic image sensor assembly including a microelectronic element having a front face, contacts exposed at the front face, a semiconductor region having a first surface adjacent the front face and the semiconductor region having a rear face remote therefrom, and first and second light sensing elements arranged to receive light of first and second different wavelengths, respectively, through a semiconductor region adjacent the rear face; and first and second regions of material overlying the rear surface of the semiconductor region and overlying the first and second light sensing elements, respectively, the first and second regions transmitting substantially different amounts of the light such that the first and second different wavelengths reach the first and second light sensing elements with substantially the same intensity despite a substantial difference in the rate at which the portion of the semiconductor region between the light sensing elements and the rear face absorbs the light of the first and second different wavelengths.

In accordance with certain embodiments of this first aspect, the assembly may further include an antireflective coating overlying the rear face of the semiconductor region. The first and second different wavelengths may correspond to different colors of light selected from the group consisting of red, blue, and green. The first and second regions may have different reflectivities with respect to a first one of the wavelengths. One of the first and second regions may be an antireflective region, and the other of the first and second regions may be substantially more reflective than the antireflective region. The first and second regions may have first and second light absorption values which are substantially different. The first and second light absorption values may be neutral with respect to the first and second wavelengths. The first and second regions may have first and second substantially different thicknesses in a direction above the rear face, the first and second thicknesses selected so as to compensate for the substantial difference in the rate at which the semiconductor region absorbs the light of the first and second different wavelengths. The first and second regions may consist essentially of the same material.

The assembly may further include a third light sensing element arranged to receive light of a third wavelength different from the first and second wavelengths through the rear face, and a third region of material overlying the rear face and overlying the third light sensing element, the third region transmitting an amount of light to the third light sensing element which is substantially different from the amounts transmitted by the first and second regions to the first and second light sensing elements, such that the third light sensing element is arranged to receive the light having the third wavelength with substantially the same intensity as the first and second light sensing elements are arranged to receive the first and second wavelengths, respectively. The first, second, and third regions may have different reflectivities. The third region may have a light absorption value which is different from the light absorption values for the first and second regions, respectively. The first, second, and third wavelengths may correspond to different colors selected from the group consisting of red, blue, and green.

The assembly may further include a substrate mounted to the front face of the microelectronic element, the substrate having a coefficient of thermal expansion of less than 10 parts per million/° C. (“ppm/° C.”), and conductive elements extending from the contacts of the microelectronic element through the substrate and exposed at a surface of the substrate remote from the microelectronic element, the conductive elements including unit contacts. The assembly may further include a color filter array including at least a first filter and a second filter overlying the first and second light sensing elements, respectively, the first and second filters having first and second different passbands selecting the first and second wavelengths, respectively. The first and second wavelengths may correspond to different ones of: red, blue, or green wavelengths. The assembly may further include an array of microlenses including first and second microlenses overlying the first and second filters, respectively. The assembly may further include a transparent cover overlying the microlenses, a cavity being disposed between the transparent cover and the microlenses.

A second aspect of the present invention is a system including a structure as described above and one or more other electronic components electrically connected to the structure. In accordance with certain embodiments of this second aspect, the system may further include a housing, the structure and the other electronic components being mounted to the housing.

A third aspect of the present invention is a method of making a microelectronic image sensor assembly, including forming first and second regions of material overlying a rear face of a monolithic semiconductor region of a microelectronic element, the first and second regions overlying first and second light sensing elements disposed within the semiconductor region, respectively, the microelectronic element having a front face opposite the rear face and a plurality of contacts exposed at the front face, and wherein the first and second regions permit substantially different amounts of light to pass such that first and second different wavelengths reach the first and second light sensing elements with substantially the same intensity despite a substantial difference in the rate at which the portion of the semiconductor region between the light sensing elements and the rear face absorbs the light of the first and second different wavelengths.

In accordance with certain embodiments of this third aspect, the method may further include forming an antireflective coating overlying the rear face of the semiconductor region prior to the step of forming the first and second regions, the first and second regions being formed over at least a portion of the antireflective coating. The first and second wavelengths may correspond to different colors of light selected from the group consisting of red, blue, and green. The microelectronic element may include a third light sensing element arranged to receive light of a third wavelength different from the first and second wavelengths through the rear face, wherein the step of forming may include forming a third region of material overlying the rear face and overlying the third light sensing element, such that the third light sensing element is arranged to receive the light having the third wavelength with substantially the same intensity as the first and second light sensing elements are arranged to receive the first and second wavelengths, respectively. The first, second, and third wavelengths may correspond to different colors selected from the group consisting of red, blue, and green.

The method may further include mounting a substrate to the front face of the microelectronic element, the substrate having a coefficient of thermal expansion of less than 10 parts per million/° C. (“ppm/° C.”), and forming conductive elements extending from contacts of the microelectronic element through the substrate and exposed at a surface of the substrate remote from the microelectronic element, the conductive elements including unit contacts. The method may further include providing a color filter array including at least a first filter and a second filter overlying the first and second light sensing elements, respectively, the first and second filters having first and second different passbands selecting the first and second wavelengths, respectively. The method may further include forming an array of microlenses including microlenses overlying the first and second filters, respectively. The method may further include mounting a transparent cover overlying the microlenses, the microlenses being disposed within a cavity between the first and second filters and the transparent cover. The first and second regions may have first and second different reflectivities, respectively, relative to the light reaching the first and second regions. One of the first and second regions may be an antireflective region, and the other of the first and second regions may be substantially more reflective than the antireflective region. The first region may include a first material having a first light absorption value and the second region may include a second material having a second light absorption value which is substantially different from the first light absorption value. The first and second regions may have first and second substantially different thicknesses in a direction above the rear face, the first and second thicknesses selected so as to compensate for the substantial difference in the rate at which the semiconductor region absorbs the light of the first and second different wavelengths. The first and second regions may consist essentially of the same material.

Further aspects of the invention provide systems which incorporate microelectronic structures according to the foregoing aspects of the invention, composite chips according to the foregoing aspects of the invention, or both in conjunction with other electronic devices. For example, the system may be disposed in a single housing, which may be a portable housing. Systems according to preferred embodiments in this aspect of the invention may be more compact than comparable conventional systems.

### BRIEF DESCRIPTION OF THE DRAWINGS

FIGS. 1-3 are sectional views of a microelectronic element in accordance with a first embodiment of the present invention.

FIG. 4 is a sectional view of the element of FIGS. 1-3.

FIG. 5 is a sectional view of the element of FIG. 4 having a metal grid.

FIG. 6 is a sectional view of the element of FIG. 5 having a color filter array.

FIG. 7 is a sectional view of a microelectronic image sensor assembly including the element of FIG. 6.

FIG. 8 is a sectional view of another microelectronic image sensor assembly in accordance with an embodiment of the present invention.

FIG. 9 is a sectional view of another microelectronic image sensor assembly in accordance with an embodiment of the present invention.

FIG. 10 is a sectional view of another microelectronic image sensor assembly in accordance with an embodiment of the present invention.

FIG. 11 is a schematic depiction of a system according to one embodiment of the invention.

### DETAILED DESCRIPTION

One particular challenge of designing BSI image sensors and assemblies incorporating them is to ensure that the light sensing elements therein adequately receive the different wavelengths of light for which they are designed to operate. In color BSI image sensors, some light sensing elements are arranged to sense blue light, while others sense red or green light. A particular challenge of color BSI image sensors is that the semiconductor material through which the light passes to reach the light sensing elements absorbs different wavelengths of light at substantially different rates. For example, silicon absorbs visible light in the blue wavelength range at a rate about five times the rate silicon absorbs visible light in the red wavelength range. Consequently, when a BSI image sensor has a uniform thickness of silicon overlying the light sensing elements, the light sensing elements which receive the blue light receive substantially lower intensity than the light sensing elements which receive the red light. Since the green wavelength range lies between blue and red, the light sensing elements which receive the green light receive substantially lower intensity than the light sensing elements which receive the red light.

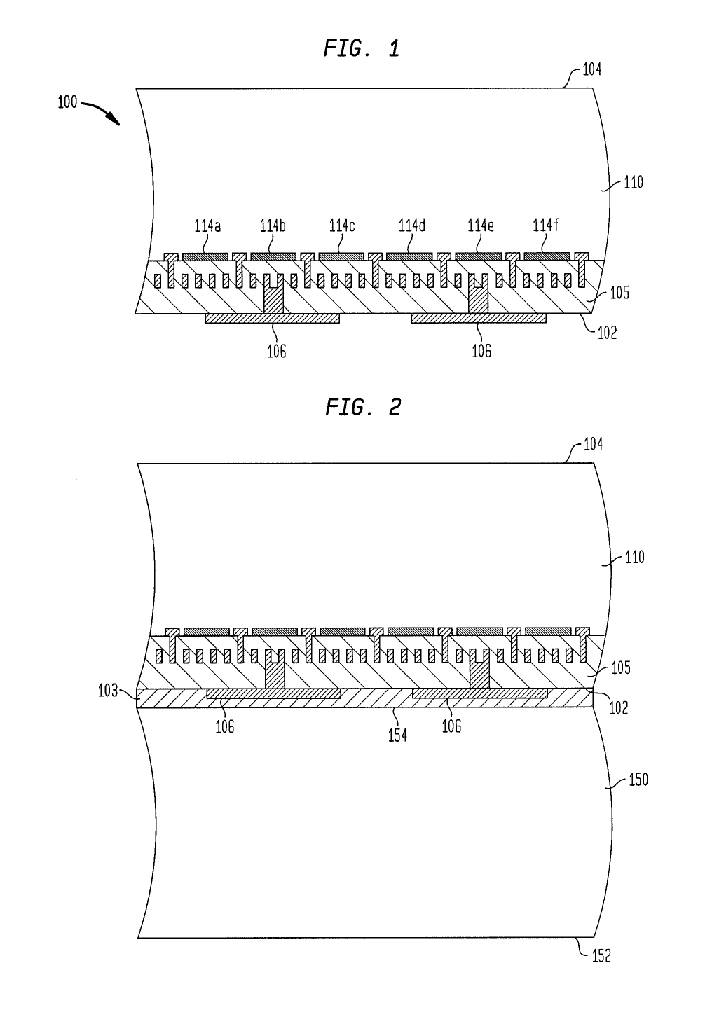

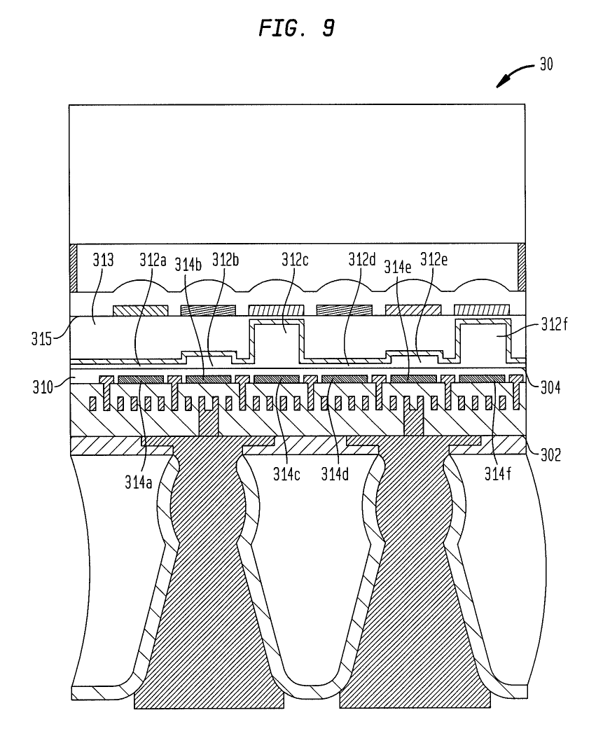

Particular embodiments of the invention address these challenges. For example, FIGS. 1-7 depict various stages in formation of a microelectronic image sensor assembly 10 according to one embodiment of the present invention. In the embodiment shown in FIG. 7, a microelectronic image sensor assembly 10 is provided which includes a microelectronic element 100 having a front face 102 and a rear face 104 remote from front face 102. One or more contacts 106 are exposed at front face 102 of the microelectronic element. A circuitry portion 105 typically includes a plurality of wiring levels and provides electrical interconnection between internal elements within the microelectronic element 100 and between such internal elements and the contacts 106.

A plurality of light sensing elements (“LSEs”) 114, i.e., 114a, 114b, 114c, 114d, 114e, and 114f as shown according to their respective positions in the assembly, are arranged to receive light through the rear face 104. Hereinafter, the LSEs at these positions may be collectively referred to as LSEs “114a-f”. The LSEs typically are photodiodes but can be other types of photodetectors. Such devices typically are active circuit elements having at least portions formed in a semiconductor region 110 of the microelectronic element 100. The circuitry portion 105 provides interconnection between the LSEs 114 and the contacts 106 so as to permit signals representing the output of the LSEs to be output via the contacts. Typically, the image sensor assembly 10 contains thousands or millions of LSEs, such that the arrangement seen in FIG. 7 can be repeated thousands or millions of times. As arranged within the microelectronic assembly, some of the LSEs are arranged to receive light of a first wavelength or first band of wavelengths, while other LSEs are arranged to receive light of a second wavelength of second band of wavelengths different from the first wavelength or first band. Still other LSEs can be arranged to receive light of a third wavelength or third band of wavelengths which is different from each of the first and second wavelengths or first and second bands.

In one embodiment, each of the LSEs can be identical and be designed to operate over a fairly wide range of wavelengths, and the microelectronic assembly 10 can include features which restrict the light that LSEs receive to narrower ranges of wavelengths or to particular wavelengths. For example, the assembly 10 can include a color filter array which includes filters 108a, 108b, 108c, 108d, 108e, and 108f (collectively, “108a-f”) overlying respective ones of the LSEs 114a, 114b, 114c, 114d, 114e, and 114f. At least some of such filters 108a-f have different passbands which select corresponding different wavelengths. For example, filter 108a can have a passband which selects blue wavelength light, therefore selectively transmitting blue wavelength light while blocking the transmission of light for wavelengths other than blue wavelength. Similarly, filter 108b can have a passband which selects green wavelength light, and selectively transmits green wavelength light while blocking the transmission of light for wavelengths other than for green wavelength. Finally, filter 108c can have a passband which selects red wavelength light, and selectively transmits red wavelength light while blocking the transmission of light for wavelengths other than for red wavelength. There may be a small overlap or no overlap between the passbands of the filters. In the embodiment shown in FIG. 7, filters 108d, 108e and 108f may function similarly to filters 108a, 108b and 108c, respectively, such that filters 108a, 108d transmit blue wavelength light, filters 108b, 108e transmit green wavelength light and filters 108c, 108f transmit red wavelength light.

In one embodiment, semiconductor region 110 may consist essentially of silicon. As seen in FIG. 7, rear face 104 overlies LSEs 114a-f. Areas 112a-f also overlie rear face 104 and LSEs 114a-f, respectively, and can have different reflectivities with respect to one of the wavelengths of light. For example, area 112a is disposed above LSE 114a, i.e., between LSE 114a and filter 108a, an area 112b is disposed between LSE 114b and filter 108b, and so on, to define additional areas 112c, 112d, 112e, and 112f.

Any or all of areas 112 can be comprised of different materials that permit substantially different amounts of light to pass therethrough. Light absorption values for the different materials in two of areas 112 can be neutral with respect to different wavelengths. One of the areas 112 can be comprised of a material that is an antireflective layer. Another of the areas 112 can be comprised of a material that is a layer adapted to reflect a greater amount of light than the antireflective layer. Further, one area 112 can be comprised of a material having a light absorption value different from a light absorption value of the material of another area 112. Suitable materials having higher absorption coefficients than the silicon material of which the semiconductor region 110 between the LSEs and the rear face 104 typically consists include various forms of doped silicon, such as indium-doped silicon or boron-doped silicon, for example. Still other examples of materials that can serve as one or more increased materials having increased absorption coefficients include gallium arsenide (GaAs), indium phosphide (InP), germanium (Ge), etc., and other materials, such as aluminum oxide or other ceramics, among others.

The different areas 112 affect the light passing therethrough. By making the properties of areas 112 different, the greater absorption rate of shorter (e.g., blue) wavelengths by the semiconductor material beneath areas 112, e.g. silicon, can be compensated by a corresponding change in the reflectivity or absorption of the areas 112 overlying the LSEs 114 which receive the blue light.

As discussed above, semiconductor materials such as silicon can absorb shorter wavelength light, e.g., blue light, at a much greater rate than red light. For example, the absorption rate of blue light in silicon is about five times the absorption rate of red light. In addition, the absorption rate of blue light in silicon is about 1.5 times the absorption rate of green light. To compensate for these differences in the absorption rate, when the semiconductor region 110 in the embodiment depicted in FIG. 7 consists essentially of silicon, the relative reflectivity of material at area 112c, for example, can cause red light received thereat to be reflected at a higher rate, e.g., about five times the rate at which light is reflected due to the reflectivity of the material at area 112a that receives blue light. In an embodiment, the relative reflectivity of the area 112c that receives green light can cause light to be reflected therefrom at a rate about 1.5 times the rate at which the blue light is reflected from area 112a due to its relative reflectivity. Thus, red light that passes through filter 108c passes through area 112c that has greater reflectivity than does the green light which passes through filter 108b. In addition, the green light passes through area 112b that has greater reflectivity than does the blue light which passes through filter 108a. In this way, the products of the absorption rates of the semiconductor material for different wavelengths and the reflectivities of the respective regions 112 can be made substantially equal, such that the intensity of light received by each LSE 114a-f can be substantially the same despite the differences in the wavelengths each LSE receives and despite the different absorption rates of the semiconductor material for each of the different wavelengths.

Certain benefits can arise from such operation. With each LSE receiving substantially the same intensity of light as any other regardless of the wavelength and despite substantial differences in the rate at which the semiconductor region absorbs the light of the different wavelengths, transmission becomes homogenized, with more uniform transmission of photons to the underlying photodiodes. Also, some light sensing elements, e.g., those arranged to receive blue light, may collect more photons without having to increase the area of the assembly. In one embodiment, any variation in the transmitted intensity of the light of different wavelengths, e.g., red, green, or blue wavelengths, to the respective LSEs, can be less than thirty percent across all the different wavelengths received by the LSEs. In a particular example, the variation in transmitted intensity to the LSEs of all the different wavelengths of light can be less than ten percent.

As further depicted in FIG. 7, front face 102 of microelectronic element 100 is mounted to a first surface 152 of a substrate 150. Substrate 150 may have a coefficient of thermal expansion of less than 10 parts per million/° C. (“ppm/° C.”), such as may be when the substrate consists essentially of a semiconductor such as silicon, glass, or ceramic material, for example. A second surface 154 of substrate 150 is remote from first surface 152. Conductive vias 156, 157 extend from first surface 152 to second surface 154. The vias 156 can be aligned with contacts 106 exposed at front face 102 of microelectronic element 100 or in a variation thereof, may not be aligned with the contacts. Metal elements extend within vias 156, 157 to electrically connect contacts 106 with contact portions 158, 159 exposed at second surface 154 of substrate 150.

As further shown in FIG. 7, a microlens 124 of a microlens array can overlie each filter 108 and help to focus light onto a respective LSE 114. Overlying the microlenses 124 is a transparent cover 160 or other element comprised of glass or other transparent material. Incoming light passes through cover 160 prior to passing through microlenses 124 and being filtered according to different wavelengths by filters 108a-f. A cavity 162 is disposed between cover 160 and microlenses 124. Cavity 162 can be filled with air or gas. A supporting structure 164 can surround the cavity and support cover 160 above microelectronic element 100. In a particular embodiment, the transparent element 160 can have features (not shown) which allow it to serve an optical function, such as a refractive or diffractive optical element for the light which passes through it.

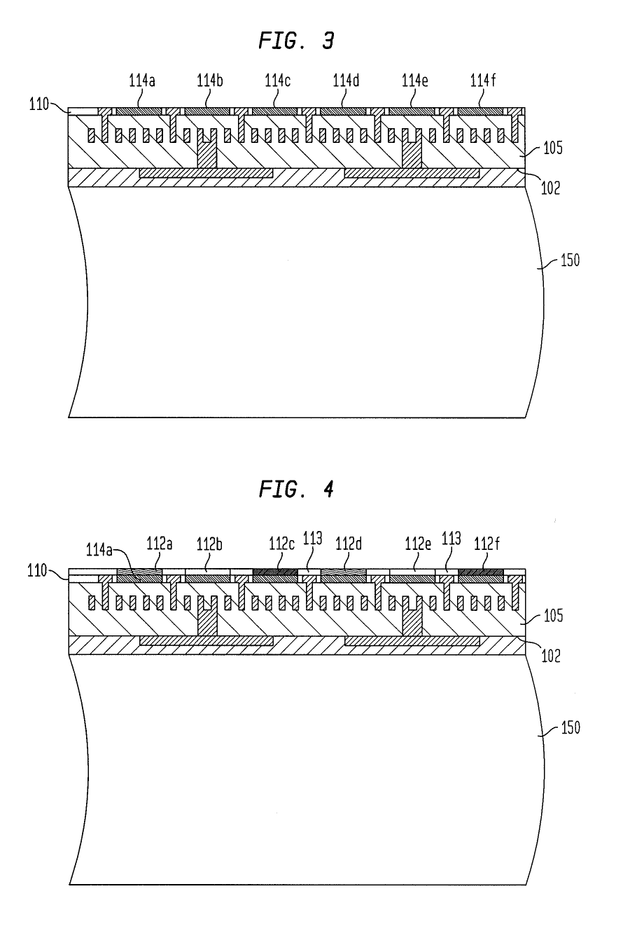

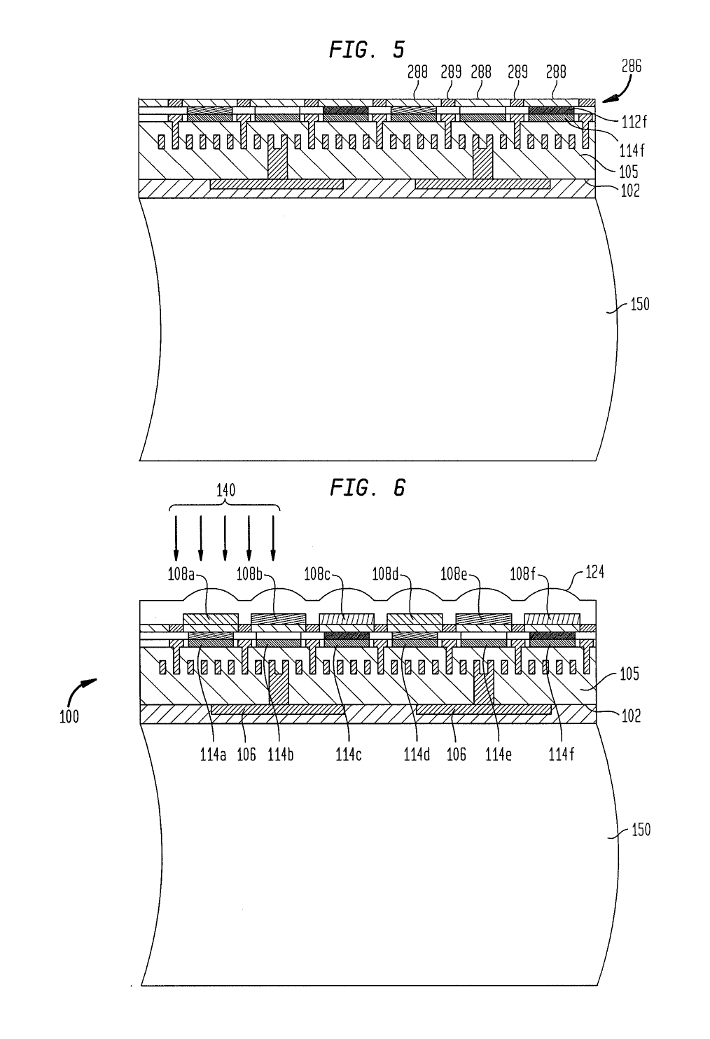

A method of making assembly 10 will now be described with reference to FIGS. 1-7. A microelectronic element 100 (FIG. 1), e.g., a wafer including semiconductor region 110, light sensing elements 114a-f, circuitry portion 105, and contacts 106 thereon, shown in FIG. 1, can be bonded to substrate 150 (FIG. 2), via an adhesive 103 or other dielectric material, for example. The semiconductor region 110 can then be thinned, such as by grinding, lapping or polishing, as shown in FIG. 3. In an embodiment, little to no thickness of the semiconductor region 110 remains between the LSEs 114 and the rear face 104. Areas 112 having different degrees of reflectivity, e.g., being either relatively anti-reflective, or more reflective, can be formed atop the LSEs 114, as shown in FIG. 4. Alternatively, the areas 112a-f can be selected from relatively anti-reflective, more anti-reflective, and relatively reflective. Between neighboring individual areas, e.g., areas 112a, 112b, filler areas 113 may be provided. The filler areas 113 may have the same or different reflectivity as one or more of the areas 112a, 112b, etc., which are used to compensate for wavelength-dependent absorption in the silicon region 110. For example, the filler areas may consist essentially of a polymer having a controlled amount of filler material therein.

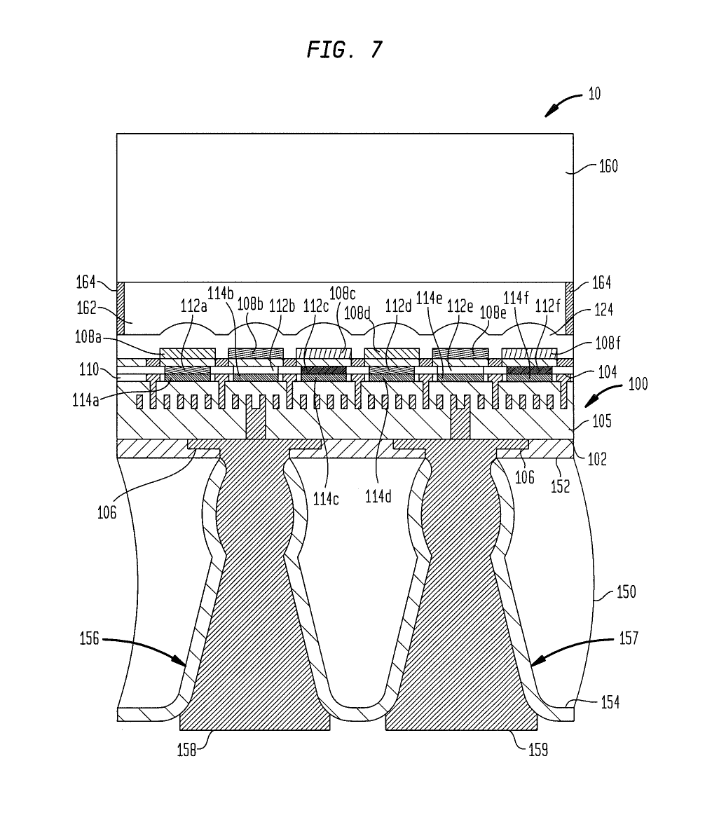

As shown in FIG. 5, a metal grid 286 can be formed atop the structure to overlie filler areas 113. Metal grid 286 may define apertures 288 overlying each LSE 214 to allow light to pass through grid 286 via apertures 288 to reach each respective LSE 214. Portions 289 of grid 286 can be comprised of metal and are arranged to overlie space between adjacent LSEs 214. Portions 289 serve to reduce or substantially eliminate cross-talk of the passing light between adjacent LSEs 214.

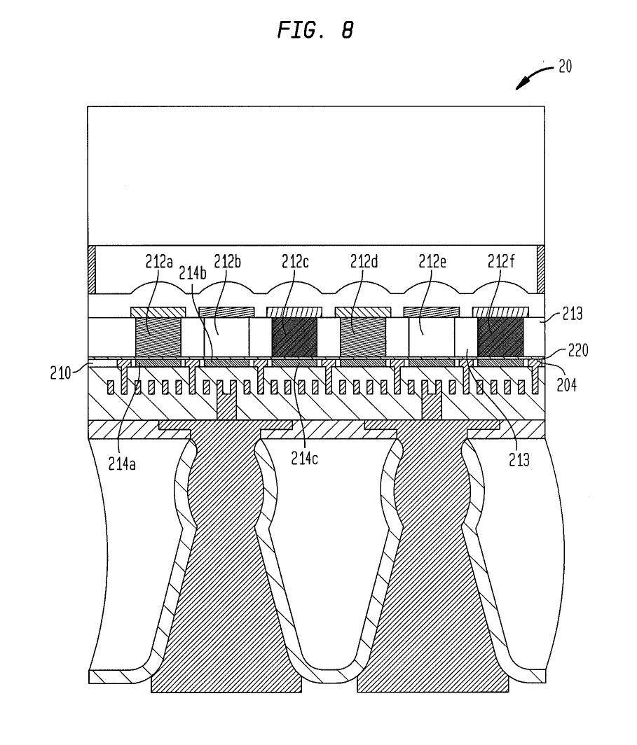

FIG. 6 illustrates the formation of a color filter array above the LSEs including filters 108a, 108b, 108c, etc., above respective ones of LSEs 114a, 114b, 114c, etc. An array of microlenses including microlens 124 is arranged overlying a respective LSE of the array of LSEs 114a-f. In further processing (FIG. 7), a wafer-sized transparent cover or other element 160 can be mounted above the rear face 104 of the wafer and be supported thereon by supporting structure 164. Conductive elements 158, 159 can be formed which extend from contacts 106 and are exposed at an exterior face 154 of the microelectronic assembly 110. A method of forming the conductive elements can be as described in one or more of the following commonly owned applications, the disclosures of which are incorporated herein by reference: U.S. Publication No. 2008/0246136 and U.S. Application Nos. 61/419,033 and 61/419,037. When a wafer-level fabrication method is used to produce the structure shown in FIG. 7 as contemplated in one embodiment herein, the structure at this stage of fabrication can include a device wafer including a plurality of microelectronic elements 100, a transparent cover element 160 or transparent wafer overlying the substantially planar surfaces of the microelectronic elements therein, and a carrier wafer, passive wafer or other substrate 150 overlying the front face 102 of the device wafer. The structure can be severed into a plurality of individual microelectronic assemblies 10, each including a microelectronic element 100, a transparent element 160 supported above the rear face of such microelectronic element, and a portion of the substrate 150 overlying the front face of such microelectronic element 100.

FIG. 8 depicts a microelectronic image sensor assembly 20 according to a second embodiment of the present invention. Assembly 20 is similar in nearly all respects as assembly 10 as described above. However, the main difference is that areas 112 of different reflectivities are replaced with different materials 212a-f having different light transmission properties defined by fillers present in each material 212. Such fillers may differ by particle size, density, and/or type, and each material 212 may have a different surface finish. Between neighboring individual areas 212, e.g., areas 212a, 212b, filler areas 213 may be provided. The filler areas 213 may have even greater absorption values as one or more of the areas 212a, 212b, etc. described above. It may not necessary to include a metal grid in connection with assembly 20. Further, assembly 20 may include an antireflective coating 220 overlying semiconductor region 210, antireflective coating 220 separating the semiconductor region 210 from areas 212a-f and filler areas 213. The antireflective coating 220 can be deposited over semiconductor region 210 such that it conformally covers the rear face 204, including the features therein. In a particular example, without limitation, the antireflective coating 220 can be formed by sputtering.

FIG. 9 depicts a microelectronic image sensor assembly 30 according to a third embodiment of the present invention. Assembly 20 is similar in nearly all respects as assembly 10 as described above. However, the main difference is that areas 112 of different reflectivities are replaced with regions 312a-f of material having a high refractive index that are patterned to different thickness, such that the intensity of light transmitted to respective LSEs 314a, 314b, 314c is the same or approximately the same. The thickness of each region 312a-f above the rear face 304 can be determined according to the properties of the material used for each region 312. In one embodiment, the same material can be used for each of the six regions 312a-f illustrated in FIG. 9. In this case, the thickness of each of the regions 312 in a direction away from the respective LSE 314 over which such region 312 lies can be selected such that the product of the light absorption in each region 312 and the light absorption in the corresponding portion of the semiconductor region 110 overlying each respective LSE is the same. In a case in which the semiconductor region 110 consists essentially of silicon and the absorption rate of blue light in the semiconductor region overlying LSEs 314a, 314d is about five times the absorption rate of red light, then the thickness of the material in the overlying regions 312a, 312d overlying the LSEs 314c, 314f can be selected to be about five times the thickness of the material in regions 312a, 312d which overlie LSEs 314a, 314d. In that way substantially the same intensity of light is transmitted to the red and blue LSEs 314a, 314c, 314d, 314f. Similarly, when the absorption rate of green light in the semiconductor region overlying LSEs 314b, 314e is about 1.5 times the absorption rate of blue light, then the thickness of the material in regions 312b, 312e overlying the LSEs for green light can be selected to be about 1.5 times the thickness of the material in region 312 which overlies the LSEs 312a, 312d for blue light. As further seen in FIG. 9, some or all of the regions 312 can be covered with another material 313 having a high refractive index. The high refractive index material 313 may have a substantially planar surface 315 overlying front face 302. Including such high-refractive index material 313 may improve transmission of light to the LSEs 314. Further, as described above, assembly 30 may include an antireflective coating (not shown) overlying semiconductor region 310 typically below the areas of absorbing material 312a-f. In one example, the antireflective coating can separate the semiconductor region 310 from areas 312a-f. The antireflective coating can be deposited over semiconductor region 310 such that it conformally covers the rear face 304, including the features therein. In a particular example, without limitation, the antireflective coating can be formed by sputtering.

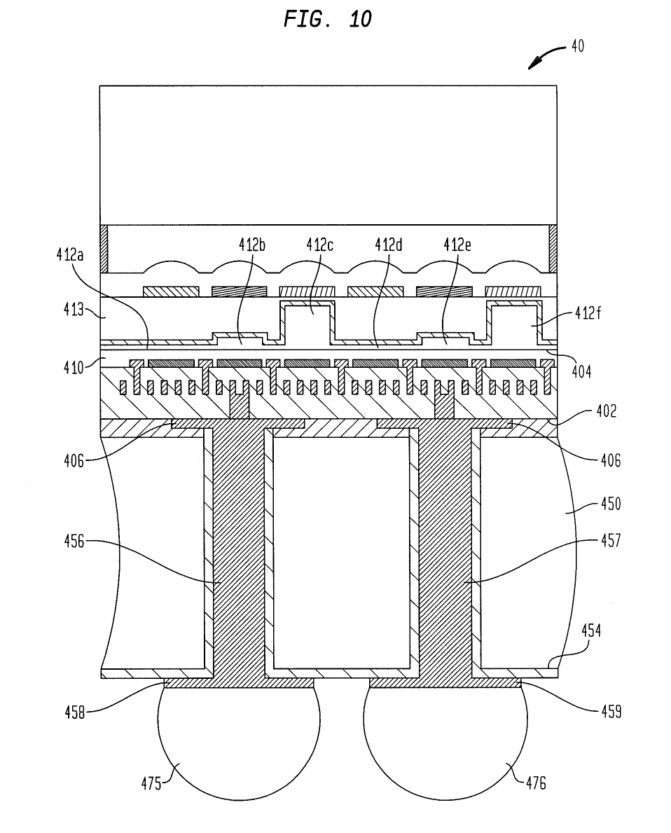

FIG. 10 depicts another embodiment of a microelectronic image sensor assembly 40 similar to assembly (FIG. 9), but having conductive vias 456, 457 having parallel walls, i.e., walls that are substantially perpendicular to front face 402. The vias 456, 457 can be aligned with contacts 406 exposed at front face 402 of microelectronic element 400 or in a variation thereof, may not be aligned with the contacts. Metal elements extend within vias 456, 457 to electrically connect contacts 406 with contact portions 458, 459 exposed at second surface 454 of substrate 450. Contact portions 458, 459 may be covered with solder bumps 475, 476 for electrical connection to external elements. As described above with respect to assembly 20 shown in FIG. 8, assembly 40 may include an antireflective coating (not shown) overlying the semiconductor region 410 and separating the semiconductor region 410 from areas 412a-f and filler areas 413. The antireflective coating can be deposited over semiconductor region 410 such that it conformally covers the rear face 404, including the features therein.

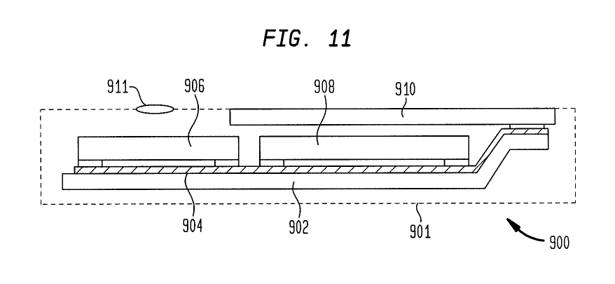

The structures discussed above provide extraordinary three-dimensional interconnection capabilities. These capabilities can be used with chips of any type. Merely by way of example, the following combinations of chips can be included in structures as discussed above: (i) a processor and memory used with the processor; (ii) plural memory chips of the same type; (iii) plural memory chips of diverse types, such as DRAM and SRAM; (iv) an image sensor and an image processor used to process the image from the sensor; (v) an application-specific integrated circuit (“ASIC”) and memory. The structures discussed above can be utilized in construction of diverse electronic systems. For example, a system 900 in accordance with a further embodiment of the invention includes a structure 906 as described above in conjunction with other electronic components 908 and 910. In the example depicted, component 908 is a semiconductor chip whereas component 910 is a display screen, but any other components can be used. Of course, although only two additional components are depicted in FIG. 11 for clarity of illustration, the system may include any number of such components. The structure 906 as described above may be, for example, a composite chip as discussed above or a structure incorporating plural chips. In a further variant, both may be provided, and any number of such structures may be used. Structure 906 and components 908 and 910 are mounted in a common housing 901, schematically depicted in broken lines, and are electrically interconnected with one another as necessary to form the desired circuit. In the exemplary system shown, the system includes a circuit panel 902 such as a flexible printed circuit board, and the circuit panel includes numerous conductors 904, of which only one is depicted in FIG. 11, interconnecting the components with one another. However, this is merely exemplary; any suitable structure for making electrical connections can be used. The housing 901 is depicted as a portable housing of the type usable, for example, in a cellular telephone or personal digital assistant, and screen 910 is exposed at the surface of the housing. Where structure 908 includes a light-sensitive element such as an imaging chip, a lens 911 or other optical device also may be provided for routing light to the structure. Again, the simplified system shown in FIG. 11 is merely exemplary; other systems, including systems commonly regarded as fixed structures, such as desktop computers, routers and the like can be made using the structures discussed above.

As these and other variations and combinations of the features discussed above can be utilized without departing from the present invention, the foregoing description of the preferred embodiments should be taken by way of illustration rather than by way of limitation of the invention as defined by the claims.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic image sensor assembly, comprising:
a microelectronic element having a front face, contacts exposed at the front face, a semiconductor region having a first surface adjacent the front face and the semiconductor region having a rear face remote therefrom, and first and second light sensing elements arranged to receive light of first and second different wavelengths, respectively, through the semiconductor region adjacent the rear face, wherein the semiconductor region comprises a material having a property so as to absorb the light of the first and second different wavelengths at substantially different rates; and
first and second regions of material overlying the rear face of the semiconductor region, overlying the first and second light sensing elements, respectively, and arranged to receive the light of the first and second different wavelengths, respectively, wherein the first region is configured to transmit a substantially different amount of the light of the first wavelength than the amount of the light of the second wavelength that the second region is configured to transmit,
such that the first and second regions of material are configured to attenuate the light of the first and second different wavelengths, respectively, to different degrees so as to compensate for the difference in absorption of the light of the first and second wavelengths by the semiconductor region in the paths of the light therethrough to the first and second light sensing elements, respectively.

2. The assembly of claim 1, further comprising an antireflective coating overlying the rear face of the semiconductor region.

3. The assembly of claim 1, wherein the first and second different wavelengths correspond to different colors of light selected from the group consisting of red, blue, and green.

4. The assembly of claim 1, wherein the first and second regions have different reflectivities with respect to a first one of the wavelengths.

5. The assembly of claim 1, wherein one of the first and second regions is an antireflective region, and the other of the first and second regions is substantially more reflective than the antireflective region.

6. The assembly of claim 1, wherein the first and second regions have first and second light absorption values which are substantially different.

7. The assembly of claim 6, wherein the first and second light absorption values are neutral with respect to the first and second wavelengths.

8. The assembly of claim 1, wherein the first and second regions have first and second substantially different thicknesses in a direction above the rear face, the first and second thicknesses selected so as to compensate for the substantial difference in the rate at which the semiconductor region absorbs the light of the first and second different wavelengths.

9. The assembly of claim 8, wherein the first and second regions consist essentially of the same material.

10. The assembly of claim 1, further comprising a third light sensing element arranged to receive light of a third wavelength different from the first and second wavelengths through the semiconductor region, and a third region of material overlying the rear face of the semiconductor region and overlying the third light sensing element, the third region being configured to attenuate the light of the third wavelength to a different degree than the degrees of attenuation which the first and second regions of material are configured to provide, such that the first, second, and third regions are configured to compensate for the difference in absorption of the light of the first, second, and third wavelengths by the semiconductor region in the paths of the light therethrough to the first, second, and third light sensing elements, respectively.

11. The assembly of claim 10, wherein the first, second, and third regions have different reflectivities.

12. The assembly of claim 10, wherein the third region has a third light absorption value which is different from first and second light absorption values of the first and second regions, respectively.

13. The assembly of claim 10, wherein the first, second, and third wavelengths correspond to different colors selected from the group consisting of red, blue, and green.

14. The assembly of claim 1, further comprising a substrate mounted to the front face of the microelectronic element, the substrate having a coefficient of thermal expansion of less than 10 parts per million/° C. (“ppm/° C.”), and conductive elements extending from the contacts of the microelectronic element through the substrate and exposed at a surface of the substrate remote from the microelectronic element, the conductive elements including unit contacts.

15. The assembly of claim 1, further including a color filter array including at least a first filter and a second filter overlying the first and second light sensing elements, respectively, the first and second filters having first and second different passbands selecting the first and second wavelengths, respectively.

16. The assembly of claim 15, wherein the first and second wavelengths correspond to different ones of: red, blue, or green wavelengths.

17. The assembly of claim 15, further including an array of microlenses including first and second microlenses overlying the first and second filters, respectively.

18. The assembly of claim 17, further including a transparent cover overlying the microlenses, a cavity being disposed between the transparent cover and the microlenses.

19. A system comprising a structure according claim 1 and one or more other electronic components electrically connected to the structure.

20. A system as claimed in claim 19 further comprising a housing, said structure and said other electronic components being mounted to said housing.

21. A method of making a microelectronic image sensor assembly as claimed in claim 1, comprising:
forming the first and second regions of material overlying the rear face of the semiconductor region of the microelectronic element, such that the first and second regions overlie the first and the second light sensing elements disposed within the semiconductor region, respectively.

22. The method of claim 21, further comprising forming an antireflective coating overlying the rear face of the semiconductor region prior to the step of forming the first and second regions, the first and second regions being formed over at least a portion of the antireflective coating.

23. The method of claim 21, wherein the first and second wavelengths correspond to different colors of light selected from the group consisting of red, blue, and green.

24. The method of claim 21, wherein the microelectronic element includes a third light sensing element arranged to receive light of a third wavelength different from the first and second wavelengths through the rear face,
wherein the step of forming includes forming a third region of material overlying the rear face and overlying the third light sensing element,
wherein the first, second, and third regions are configured to compensate for the differences in absorption of the light of the first, second, and third wavelengths by the semiconductor region in the paths of the light therethrough to the first, second, and third light sensing elements, respectively.

25. The method of claim 24 wherein the first, second, and third wavelengths correspond to different colors selected from the group consisting of red, blue, and green.

26. The method of claim 21, further comprising mounting a substrate to the front face of the microelectronic element, the substrate having a coefficient of thermal expansion of less than 10 parts per million/° C. (“ppm/° C.”), and forming conductive elements extending from contacts of the microelectronic element through the substrate and exposed at a surface of the substrate remote from the microelectronic element, the conductive elements including unit contacts.

27. The method of claim 21, further including providing a color filter array including at least a first filter and a second filter overlying the first and second light sensing elements, respectively, the first and second filters having first and second different passbands selecting the first and second wavelengths, respectively.

28. The method of claim 27, further comprising forming an array of microlenses including microlenses overlying the first and second filters, respectively.

29. The method of claim 28, further comprising mounting a transparent cover overlying the microlenses, the microlenses being disposed within a cavity between the first and second filters and the transparent cover.

30. The method of claim 21, wherein the first and second regions have first and second different reflectivities, respectively, relative to the light reaching the first and second regions.

31. The method of claim 21, wherein one of the first and second regions is an antireflective region, and the other of the first and second regions is substantially more reflective than the antireflective region.

32. The method of claim 21, wherein the first region includes a first material having a first light absorption value and the second region includes a second material having a second light absorption value which is substantially different from the first light absorption value.

33. The method of claim 21, wherein the first and second regions have first and second substantially different thicknesses in a direction above the rear face, the first and second thicknesses selected so as to compensate for the substantial difference in the rate at which the semiconductor region absorbs the light of the first and second different wavelengths.

34. The method of claim 33, wherein the first and second regions consist essentially of the same material.
